(19) United States
(12) Patent Application Publication
(10) Pub. No.: US 2025/0300421 A1
(43) Pub. Date: Sep. 25, 2025

(54) OPTICAL SEMICONDUCTOR DEVICE

(71) Applicant: SUMITOMO ELECTRIC DEVICE INNOVATIONS, INC., Yokohama-shi (JP)

(72) Inventors: Kuniyuki ISHII, Yokohama-shi (JP); Masanobu KAWAMURA, Yokohama-shi (JP); Hiroshi HARA, Yokohama-shi (JP); Shuuzo KIMURA, Yokohama-shi (JP)

(73) Assignee: SUMITOMO ELECTRIC DEVICE INNOVATIONS, INC., Yokohama-shi (JP)

(21) Appl. No.: 19/082,857

(22) Filed: Mar. 18, 2025

(30) Foreign Application Priority Data
Mar. 22, 2024 (JP) 2024-047047

(51) Int. Cl. H01S 5/00; H01S 5/023

(52) U.S. Cl. CPC H01S 5/005; H01S 5/023

(57) ABSTRACT

An optical semiconductor device includes a substrate on which an optical semiconductor element is mounted, a first optical system that is mounted on a first surface of the substrate and changes a direction of an optical axis of the optical semiconductor element to a direction passing through the substrate; and a second optical system that is mounted on a second surface of the substrate opposite to the first surface and coupled to the optical axis passing through the substrate.

### TECHNICAL FIELD

The present disclosure relates to an optical semiconductor device.

### BACKGROUND

Japanese Unexamined Patent Publication No. 2020-13831 discloses an optical module. This optical module includes a chip carrier in which a tunable laser element that emits laser light and a temperature detection element are mounted, a light detection element that detects the laser light output from the tunable laser element, a temperature control element in which the chip carrier and the light detection element are mounted, and a housing in which the temperature control element is housed and which has a window portion through which the laser light is output.

For example, an optical semiconductor device having an optical semiconductor element, such as a semiconductor laser element, on a substrate is used. In addition to the semiconductor laser element, various optical components arranged on the optical path of light emitted from the semiconductor laser element are mounted on the substrate of such an optical semiconductor device. On the other hand, there is a growing demand for miniaturization of optical semiconductor devices.

### SUMMARY

It is an object of the present disclosure to enable the miniaturization of an optical semiconductor device including an optical semiconductor element on a substrate.

An optical semiconductor device according to an aspect of the present disclosure includes: a substrate on which an optical semiconductor element is mounted; a first optical system that is mounted on a first surface of the substrate and changes a direction of an optical axis of the optical semiconductor element to a direction passing through the substrate; and a second optical system that is mounted on a second surface of the substrate opposite to the first surface and coupled to the optical axis passing through the substrate.

According to the present disclosure, an optical semiconductor device including an optical semiconductor element on a substrate can be made smaller.

### BRIEF DESCRIPTION OF THE DRAWINGS

FIG. 1 is a perspective view showing the configuration of an optical semiconductor device according to an embodiment of the present disclosure.

FIG. 2 is a plan view of the optical semiconductor device.

FIG. 3 is a bottom view of the optical semiconductor device.

FIG. 4 is a side cross-sectional view of the optical semiconductor device.

FIG. 5 is a drawing showing a state in which a substrate of the optical semiconductor device has been removed.

FIG. 6 is a perspective view showing a housing included in the optical semiconductor device.

FIG. 7 is a side cross-sectional view of an optical semiconductor device including a housing.

FIG. 8 is a side cross-sectional view showing a modification example.

### DETAILED DESCRIPTION

### Description of Embodiments of Present Disclosure

First, the contents of an embodiment of the present disclosure will be listed and described.

[1] An optical semiconductor device according to an embodiment of the present disclosure includes: a substrate on which an optical semiconductor element is mounted; a first optical system that is mounted on a first surface of the substrate and changes a direction of an optical axis of the optical semiconductor element to a direction passing through the substrate; and a second optical system that is mounted on a second surface of the substrate opposite to the first surface and coupled to the optical axis passing through the substrate.

[2] In the optical semiconductor device according to [1] above, the substrate may have a hole corresponding to the optical axis passing through the substrate.

[3] In the optical semiconductor device according to [1] or [2] above, the optical axis passing through the substrate may penetrate and traverse the substrate.

[4] In the optical semiconductor device according to any one of [1] to [3] above, the second optical system may extract output light of the optical semiconductor element to outside.

[5] In the optical semiconductor device according to any one of [1] to [4] above, the second optical system may cause the optical axis to pass through the substrate toward a region on the first surface of the substrate.

[6] In the optical semiconductor device according to [5] above, the optical axis passing through the substrate toward the region on the first surface of the substrate may be coupled to a third optical system arranged on the first surface.

### DETAILS OF EMBODIMENTS OF PRESENT DISCLOSURE

Specific examples of the present disclosure will be described below with reference to the accompanying drawings. The present disclosure is not limited to these examples, but is defined by the claims, and is intended to include all modifications within the meaning and scope equivalent to the claims. In the following description, the same elements will be denoted by the same reference numerals in the description of the drawings, and repeated description thereof will be omitted.

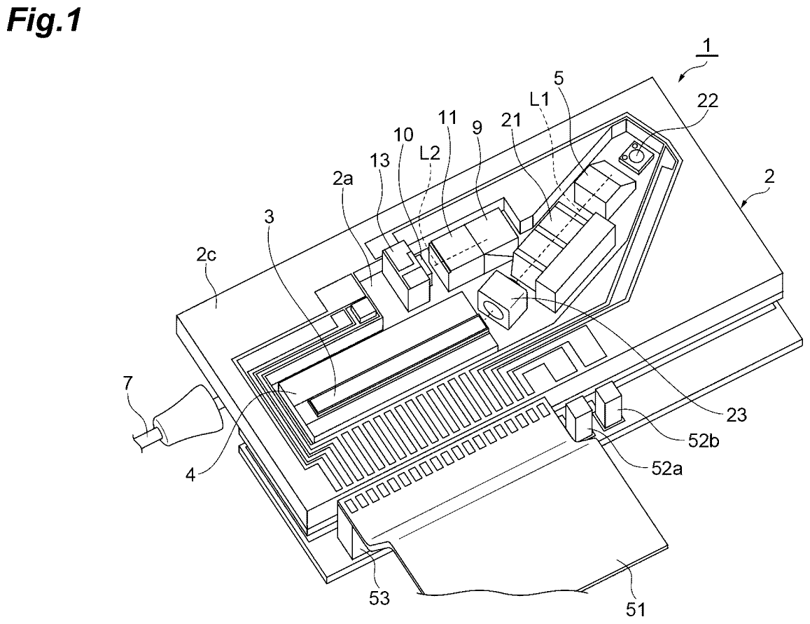

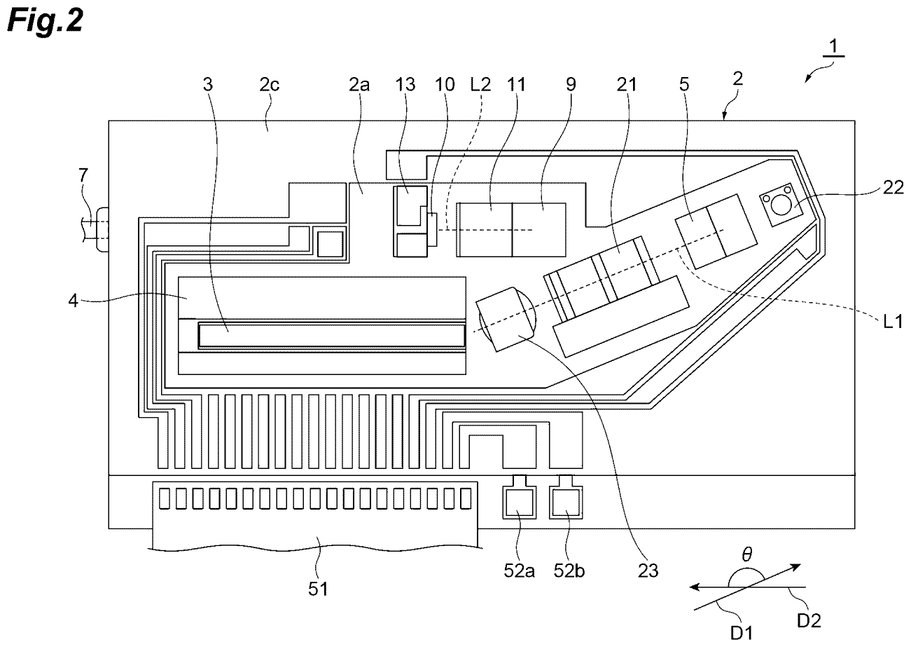

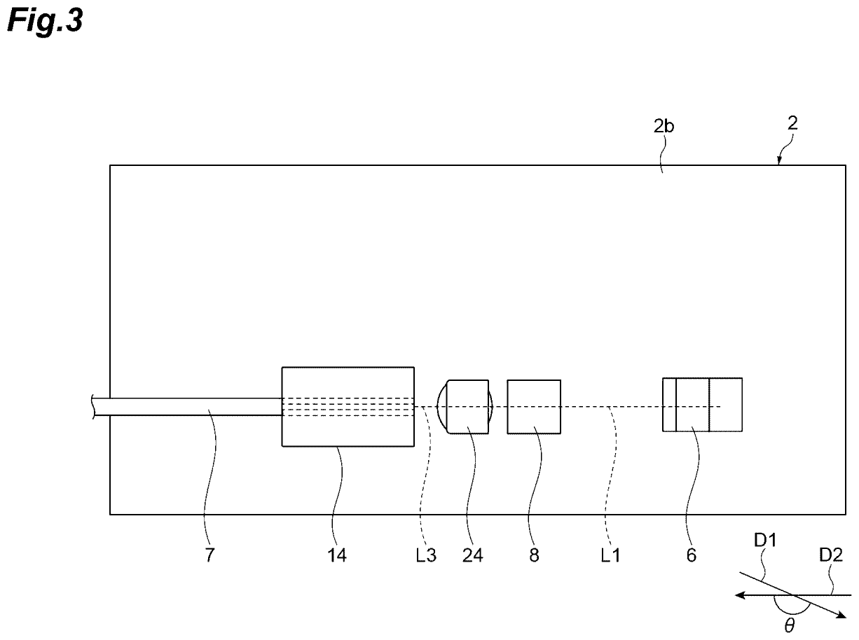

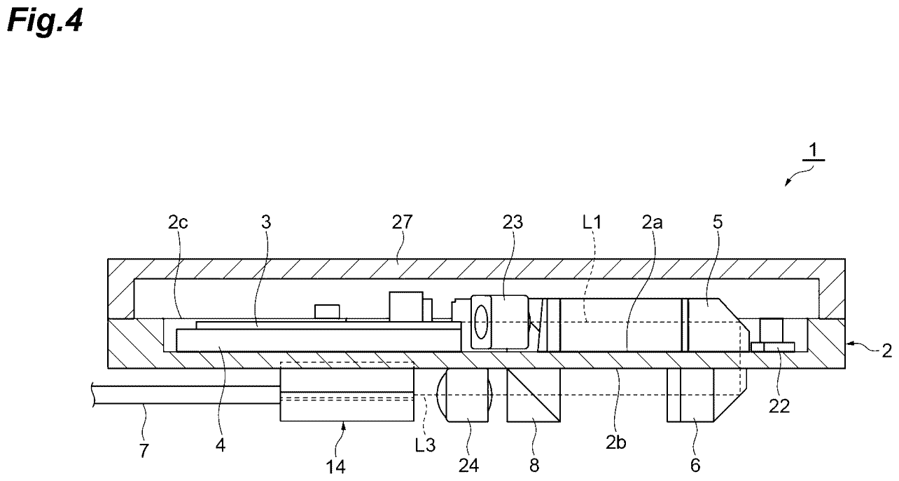

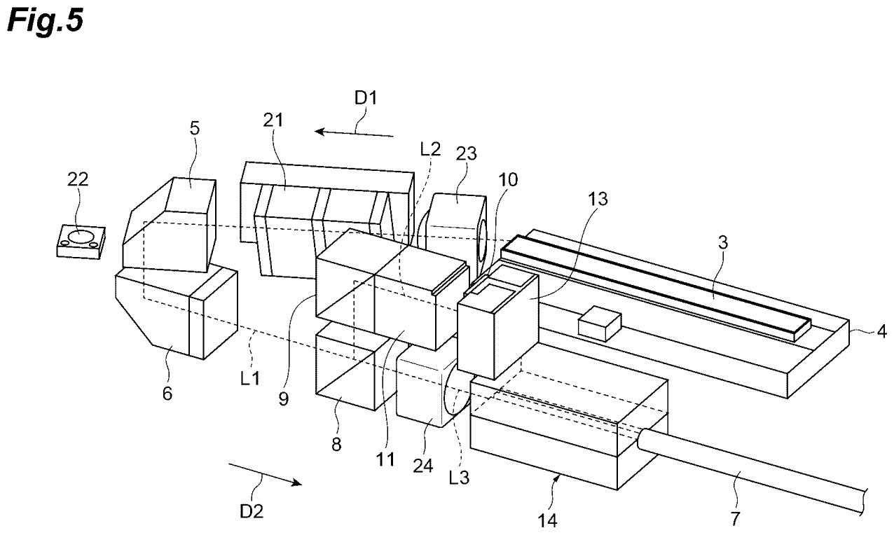

FIG. 1 is a perspective view showing the configuration of an optical semiconductor device 1 according to an embodiment of the present disclosure. FIG. 2 is a plan view of the optical semiconductor device 1. FIG. 3 is a bottom view of the optical semiconductor device 1. FIG. 4 is a side cross-sectional view of the optical semiconductor device 1. FIG. 5 is a drawing showing a state in which a substrate 2 of the optical semiconductor device 1 has been removed. As shown in FIGS. 1 to 5, the optical semiconductor device 1 according to the present embodiment includes the substrate 2, an optical semiconductor element 3, a mirror member 5, and a mirror member 6. The mirror member 5 is a first optical system in the present embodiment. The mirror member 6 is included in a second optical system in the present embodiment.

The substrate 2 is a dielectric substrate, for example, a ceramic substrate. As materials of the substrate 2, at least one of silicon (Si), glass, and aluminum nitride (AlN) is included. The material of the substrate 2 may be low temperature co-fired ceramics (LTCC). When the substrate 2 is a glass substrate, in order to improve heat dissipation, it is advisable to form vias in the substrate 2 and fill the vias with a material having good thermal conductivity, such as copper (Cu). The substrate 2 has a first surface 2a and a second surface 2b facing opposite to the first surface 2a. The first surface 2a is the bottom surface of a cavity (recess) formed on a main surface 2c of the substrate 2. The first surface 2a is a flat surface, and extends along a direction D1 (first direction). The second surface 2b is the back surface of the substrate 2. The second surface 2b is a flat surface, and extends along a direction D2 (second direction). In one example, the second surface 2b is parallel to the first surface 2a.

The optical semiconductor element 3 is arranged on the first surface 2a of the substrate 2, and is mounted on the top surface of a carrier member 4 provided on the first surface 2a. The optical semiconductor element 3 emits light L1 along the direction D1. The optical semiconductor element 3 is, for example, a semiconductor laser element. In this case, the optical semiconductor element 3 has a laser resonator extending along the direction D2, and emits laser light as the light L1 along the direction D1. The optical semiconductor element 3 may be a tunable laser element. The waveguide of the optical semiconductor element 3 is provided obliquely with respect to the longitudinal direction of the optical semiconductor element 3 in order to suppress reflected light at the end surface of the optical semiconductor element 3. Therefore, the emission direction of the light L1 is oblique to the longitudinal direction of the optical semiconductor element 3. Each of a number of electrodes provided in the optical semiconductor element 3 is electrically connected to each of a number of wirings provided on the main surface 2c.

The mirror member 5 is mounted on the first surface 2a of the substrate 2 and is fixed to the first surface 2a. The mirror member 5 changes the optical axis of the optical semiconductor element 3 to a direction passing through the substrate 2. That is, the mirror member 5 is optically coupled to the optical semiconductor element 3, receives the light L1 output from the optical semiconductor element 3, and directs the propagation direction of the light L1 toward the second surface 2b of the substrate 2. The mirror member 5 is, for example, a member transparent to the wavelength of the light L1, and is a prism having an inclined surface that reflects the light L1. The optical axis of the light L1 passes through the substrate 2. In the present embodiment, the optical axis of the light L1 penetrates and traverses the substrate 2.

The mirror member 6 is mounted on the second surface 2b of the substrate 2 and is fixed to the second surface 2b. The mirror member 6 is coupled to an optical axis passing through the substrate 2. That is, the mirror member 6 is optically coupled to the mirror member 5 with the substrate 2 interposed therebetween, and directs the light L1 having passed through the mirror member 5 in the direction D2 along the second surface 2b. Here, the direction D2 is a direction obtained by folding back the direction D1. Specifically, the vector of the direction D2 forms an angle θ larger than 90° (more preferably, an angle larger than) 150° with respect to the vector of the direction D1 (see FIGS. 2 and 3). The vector of the direction D2 forms an angle θ smaller than 180° with respect to the vector of the direction D1. A vector that forms an angle of 180° with respect to a vector in direction D1 refers to a vector that is in the opposite direction to the vector in direction D1. That is, in the present embodiment, when viewed from the thickness direction of the substrate 2, the optical path of the light L1 on the second surface 2b is inclined with respect to the optical path of the light L1 on the first surface 2a. The mirror member 6 is, for example, a member transparent to the wavelength of the light L1, and is a prism having an inclined surface that reflects the light L1. The mirror member 6 may be formed of the same material as the mirror member 5, and may have the same shape as the mirror member 5. The mirror member 6 may be configured to extract the light L1 output from the optical semiconductor element 3 to the outside of the optical semiconductor device 1.

The optical semiconductor device 1 further includes an optical fiber 7. The optical fiber 7 is configured so that the light L1 having passed through the mirror member 6 is incident on the end surface of the optical fiber 7. In the present embodiment, as will be described later, the light L1 is configured so that light L3, which is a remaining part split by a mirror member 8, is incident on the end surface of the optical fiber 7. In the illustrated example, the end surface of the optical fiber 7 is located in the direction D2 relative to the mirror member 6. The end surface of the optical fiber 7 is arranged closer to the optical semiconductor element 3 than the mirror member 5 and the mirror member 6 when viewed from the normal direction of the first surface 2a (see FIG. 5). An end portion including the end surface of the optical fiber 7 is held by a holding member 14. In the illustrated example, the holding member 14 is arranged on the second surface 2b of the substrate 2 and is fixed to the second surface 2b. The holding member 14 is formed of, for example, glass.

The optical semiconductor device 1 further includes the mirror member 8, a mirror member 9, a light detection element 10, an etalon filter 11, and a light detection element 22. The mirror member 8 is included in the second optical system in the present embodiment. The mirror member 8 is arranged on the second surface 2b of the substrate 2 and is fixed to the second surface 2b. The mirror member 8 splits light L2, which is a part of the light L1 that has passed through the mirror member 6, from the light L1, and directs the propagation direction of the light L2 toward a region on the first surface 2a of the substrate 2. The mirror member 8 is, for example, a member transparent to the wavelength of the light L1, and is a prism having an inclined surface that reflects the light L2. Thus, the second optical system may be one that causes the optical axis of the light L2 to pass through the substrate 2 toward a region on the first surface 2a of the substrate 2.

The mirror member 9 is a third optical system in the present embodiment. The mirror member 9 is arranged on the first surface 2a of the substrate 2 and is fixed to the first surface 2a. The mirror member 9 is optically coupled to the mirror member 8 with the substrate 2 interposed therebetween, and directs the light L2 having passed through the mirror member 8 in a direction along the first surface 2a. In the illustrated example, the mirror member 9 directs the light L2 in the direction D2. The mirror member 9 is, for example, a member transparent to the wavelength of the light L2, and is a prism having an inclined surface that reflects the light L2. The mirror member 9 may be formed of the same material as the mirror member 8, and may have the same shape as the mirror member 8.

The light detection element 10 is arranged above the first surface 2a of the substrate 2, and is mounted on the side surface of a carrier member 13 provided on the first surface 2a. The light detection element 10 is optically coupled to the mirror member 9. The light detection element 10 receives the light L2 having been reflected by the mirror member 8, and outputs an electrical signal according to the intensity of the light L2. The light detection element 10 is, for example, a photodiode. In this manner, since the light detection element 10 is arranged on the first surface 2a together with the optical semiconductor element 3, electrical connection between the wiring provided on the main surface 2c and the light detection element 10 can be made easily.

The etalon filter 11 is arranged on the optical path between the mirror member 8 and the light detection element 10. In the illustrated example, the etalon filter 11 is arranged on the optical path between the mirror member 9 and the light detection element 10 on the first surface 2a, and is fixed to the first surface 2a. The etalon filter 11 has a high light transmittance at a plurality of periodic wavelengths, and is used to fix the emission wavelength of the optical semiconductor element 3.

The light detection element 22 is arranged on the first surface 2a of the substrate 2 and is fixed to the first surface 2a. The light detection element 22 is arranged side by side with the mirror member 5 in the direction D1, and outputs an electrical signal according to the intensity of light of the light L1, which has passed through the light reflection surface of the mirror member 5. Therefore, it is possible to know the intensity of the light L1. By maximizing the value of the ratio between the intensity of the light L1 and the intensity of the light L2 that has passed through the etalon filter 11 and is detected by the light detection element 10, the emission wavelength of the optical semiconductor element 3 is maintained.

The optical semiconductor device 1 further includes an isolator 21, a collimator lens 23, and a condenser lens 24. The isolator 21 is arranged on the optical path of the light L1 on the first surface 2a. The isolator 21 prevents the light L1 from returning to the optical semiconductor element 3. The collimator lens 23 is arranged, on the first surface 2a, on the optical path of the light L1 between the optical semiconductor element 3 and the mirror member 5. In the illustrated example, the collimator lens 23 is arranged on the optical path of the light L1 between the optical semiconductor element 3 and the isolator 21. The collimator lens 23 collimates the light L1 emitted from the optical semiconductor element 3. The condenser lens 24 is arranged on the optical path of the light L3 between the mirror member 6 and the end surface of the optical fiber 7 on the second surface 2b. In the illustrated example, the condenser lens 24 is arranged on the optical path of the light L3 between the mirror member 8 and the end surface of the optical fiber 7. The condenser lens 24 condenses the light L3 toward the end surface of the optical fiber 7.

As shown in FIGS. 1 and 2, the optical semiconductor device 1 further includes a flexible substrate 51. The flexible substrate 51 has a plurality of terminals. Each of the plurality of terminals of the flexible substrate 51 is electrically connected to each of a plurality of wirings provided on the main surface 2c of the substrate 2.

As shown in FIG. 4, the optical semiconductor device 1 further includes a lid 27. The lid 27 is arranged so as to face the first surface 2a of the substrate 2, and covers the entire surface of the substrate 2 including the first surface 2a in an airtight manner. The material of the lid 27 is the same as that of the substrate 2, for example.

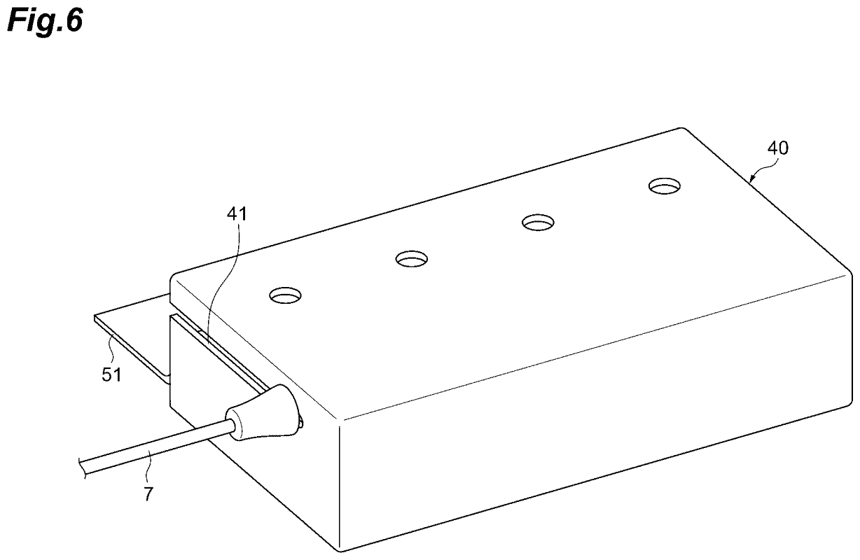

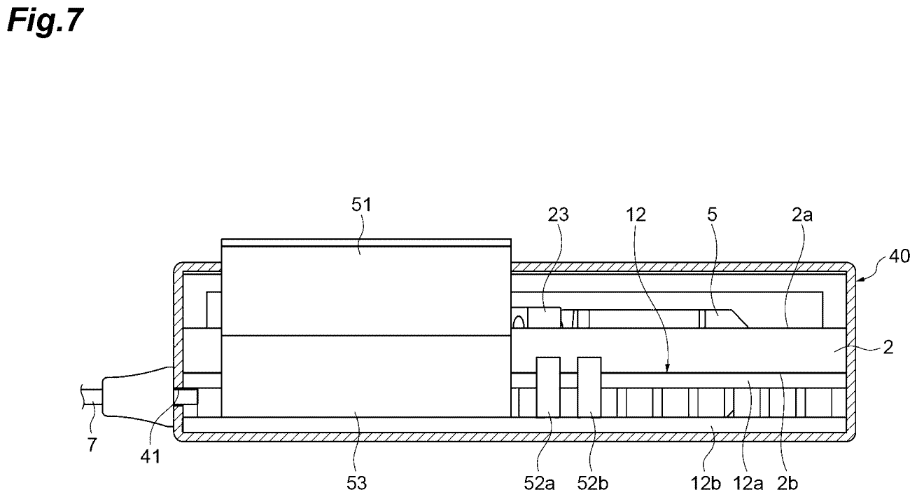

FIG. 6 is a perspective view showing a housing 40 included in the optical semiconductor device 1. FIG. 7 is a side cross-sectional view of the optical semiconductor device 1 including the housing 40. As shown in FIGS. 6 and 7, the optical semiconductor device 1 further includes the housing 40. The housing 40 has an approximately rectangular box shape, and the substrate 2 and the like are housed therein. A slit 41 is formed in the housing 40, and the optical fiber 7 is inserted through the slit 41 during assembly.

As shown in FIG. 7, the optical semiconductor device 1 further includes a temperature control element 12. The temperature control element 12 is arranged at a position facing the optical semiconductor element 3 on the second surface 2b of the substrate 2. The temperature control element 12 is a Peltier element. A plate 12a on the heat absorption side of the Peltier element is in thermal contact with the second surface 2b of the substrate 2. A plate 12b on the heat dissipation side of the Peltier element is in thermal contact with the housing 40. An electrode 52a and an electrode 52b for supplying power to the Peltier element are provided on the plate 12b. In addition, a member 53 for supporting the flexible substrate 51 is provided on the plate 12b.

The effects obtained by the optical semiconductor device 1 of the present embodiment having the above configuration will be described. In the optical semiconductor device according to the present embodiment, the light L1 emitted from the optical semiconductor element 3 on the first surface 2a of the substrate 2 along the first surface 2a is guided to the opposite surface of the substrate 2, that is, the second surface 2b, by the mirror member 5 and is further guided in the direction D2 along the second surface 2b by the mirror member 6. At this time, since the vector of the direction D2 forms an angle θ larger than 90° with respect to the vector of the direction D1, the propagation direction of the light L1 on the first surface 2a and the propagation direction of the light L1 on the second surface 2b are opposite to each other or nearly opposite to each other. In this manner, by folding back the optical path using both the surfaces of the substrate 2, that is, the first surface 2a and the second surface 2b, the optical semiconductor device 1 can be made smaller.

As in the present embodiment, the optical semiconductor device 1 may include the optical fiber 7 whose end surface is located closer to the optical semiconductor element 3 than the mirror member 5 and the mirror member 6 when viewed from the normal direction of the first surface 2a. In addition, the optical semiconductor device 1 may be configured so that the light L1 (light L3 in the present embodiment) having passed through the mirror member 6 is incident on the end surface of the optical fiber 7. In this case, the light L1 reflected by the mirror members 5 and 6 can be guided to the outside of the optical semiconductor device 1.

As in the present embodiment, the optical semiconductor device 1 may include the mirror member 8, the light detection element 10, and the etalon filter 11. The mirror member 8 is arranged on the second surface 2b of the substrate 2, and splits the light L2, which is a part of the light L1 that has passed through the mirror member 6, from the light L1, and directs the propagation direction of the light L2 toward the first surface 2a of the substrate 2. The light detection element 10 is arranged on the first surface 2a of the substrate 2, and receives the light L2 that has passed through the mirror member 8 and outputs an electrical signal according to the intensity of the light L2. The etalon filter 11 is arranged on the optical path between the mirror member 8 and the light detection element 10. In this case, the mirror member 8 that splits the light L1 and the light detection element 10 that detects the split light L2 can be arranged on different surfaces. Therefore, the optical semiconductor device 1 can be made smaller.

As in the present embodiment, the vector of the direction D2 may form an angle θ smaller than 180° with respect to the vector of the direction D1. Here, “two vectors form an angle smaller than 180°” means that straight lines along the respective vectors are inclined with respect to each other. In other words, “the vector of the direction D2 forms an angle smaller than 180° with respect to the vector of the direction D1” means that the optical path on the second surface 2b is inclined with respect to the optical path on the first surface 2a. In this case, since the optical path on the second surface 2b deviates from the optical semiconductor element 3 when viewed from the normal direction of the second surface 2b, components that should be placed close to the optical semiconductor element 3, such as the temperature control element 12, can be arranged in a region on the second surface 2b that overlaps the optical semiconductor element 3.

As in the present embodiment, the optical semiconductor element 3 may have a laser resonator extending along the direction D2, and may emit laser light as the light L1 along the direction D1. In this manner, by setting the extension direction of the laser resonator of the optical semiconductor element 3 to the direction D2, the longitudinal direction of the optical semiconductor element 3 is along the optical path on the second surface 2b. Therefore, it is possible to secure a large space on the second surface 2b for components that should be placed close to the optical semiconductor element 3.

As in the present embodiment, the optical semiconductor device 1 may include a temperature control element 12 arranged at a position facing the optical semiconductor element 3 on the second surface 2b of the substrate 2. Therefore, it is possible to control the emission wavelength of the optical semiconductor element 3.

### MODIFICATION EXAMPLES

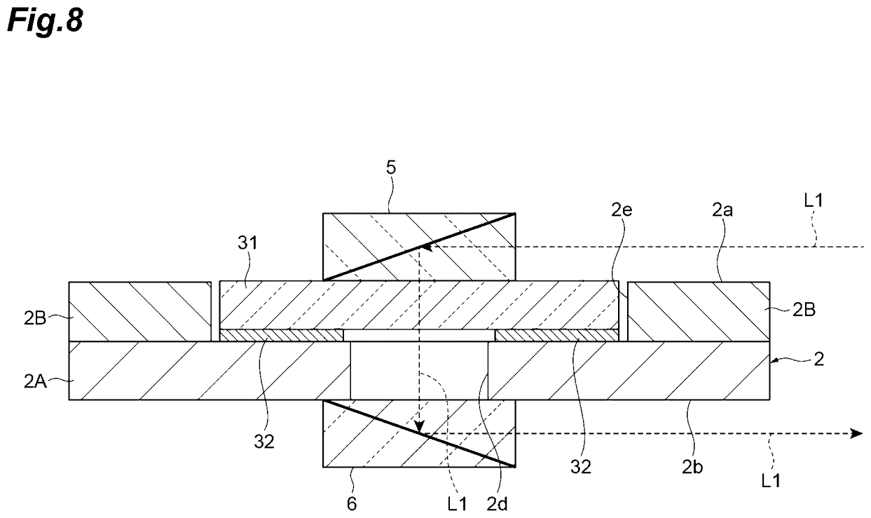

FIG. 8 is a side cross-sectional view showing a modification example of the above embodiment. In the above embodiment, the light L1 reflected by the mirror member 5 passes through the substrate 2 and reaches the mirror member 6. In this modification example, a hole, that is, an opening 2d, which is provided corresponding to the optical axis passing through the substrate 2, is provided in the substrate 2. The light L1 passes through a transparent substrate (transparent member) 31 and the opening 2d formed in the substrate 2 and reaches the mirror member 6.

Specifically, the substrate 2 in this modification example is formed by two layers, that is, a lower layer 2A and an upper layer 2B. A surface of the upper layer 2B opposite to the lower layer 2A is the first surface 2a. A surface of the lower layer 2A opposite to the upper layer 2B is the second surface 2b. Then, the opening 2d is formed in the lower layer 2A, and an opening 2e wider than the opening 2d is formed at a position of the upper layer 2B overlapping the opening 2d. On the surface of the lower layer 2A exposed from the opening 2e, the transparent substrate 31 is fixed by an adhesive 32 so as to close the opening 2d. As a result, the opening 2d is airtightly sealed. The transparent substrate 31 is, for example, a glass substrate or a sapphire substrate. An anti-reflection film (AR coat) may be provided on the transparent substrate 31. The adhesive 32 is, for example, a low melting point glass or a metallic brazing material such as AuSn solder. The mirror member 5 is arranged on the transparent substrate 31. The transparent substrate 31 has a light transmittance of 90% or more at the wavelength of the light L1.

By making the light L1 propagate through the transparent substrate 31 as in this modification example, the loss of the light L1 can be reduced compared to the case where the light L1 is transmitted through the substrate 2. In particular, when the material of the substrate 2 is aluminum nitride (AlN), the configuration of this modification example is effective because aluminum nitride has a lower light transmittance than glass and silicon.

The optical semiconductor device according to the present disclosure is not limited to the above-described embodiment and modification example, and various other modifications can be made. For example, in the above embodiment, a case is illustrated in which the angle θ between the vector of the direction D1 and the vector of the direction D2 is less than 180°, that is, the optical path of the light L1 on the second surface 2b is inclined with respect to the optical path of the light L1 on the first surface 2a. If there is no need to arrange the temperature control element 12, the angle θ between the vector of the direction D1 and the vector of the direction D2 may be 180°, that is, the optical path of the light L1 on the second surface 2b may be parallel to the optical path of the light L1 on the first surface 2a.

In the above embodiment, the end surface of the optical fiber 7 is located on the second surface 2b of the substrate 2, but the end surface of the optical fiber 7 may be located on the first surface 2a of the substrate 2. In this case, a mirror member for reflecting the light L1 (or the light L3) propagating on the second surface 2b toward the first surface 2a may be further provided on the second surface 2b.

While the principles of the present disclosure have been illustrated and described in a preferred embodiment, it is recognized by those skilled in the art that the present disclosure can be changed in arrangement and detail without departing from such principles. The present disclosure is not limited to the specific configuration disclosed in the present embodiment. Therefore, we claim all modifications and changes that come within the scope and spirit of the claims.

What is claimed is:

1. An optical semiconductor device, comprising:
a substrate on which an optical semiconductor element is mounted;
a first optical system that is mounted on a first surface of the substrate and changes a direction of an optical axis of the optical semiconductor element to a direction passing through the substrate; and
a second optical system that is mounted on a second surface of the substrate opposite to the first surface and coupled to the optical axis passing through the substrate.

2. The optical semiconductor device according to claim 1,
wherein the substrate has a hole corresponding to the optical axis passing through the substrate.

3. The optical semiconductor device according to claim 1,
wherein the optical axis passing through the substrate penetrates and traverses the substrate.

4. The optical semiconductor device according to claim 1,
wherein the second optical system extracts output light of the optical semiconductor element to outside.

5. The optical semiconductor device according to claim 1,
wherein the second optical system causes the optical axis to pass through the substrate toward a region on the first surface of the substrate.

6. The optical semiconductor device according to claim 5,
wherein the optical axis passing through the substrate toward the region on the first surface of the substrate is coupled to a third optical system arranged on the first surface.
